(19) United States
(12) Patent Application Publication
(10) Pub. No.: US 2025/0372187 A1
(43) Pub. Date: Dec. 4, 2025

(54) STAGGERING PROGRAM VERIFY OPERATIONS TO MANAGE POWER CONSUMPTION IN A MEMORY SUB-SYSTEM

(71) Applicant: Micron Technology, Inc., Boise, ID (US)

(72) Inventors: Yu-Chung Lien, San Jose, CA (US); Zhenming Zhou, San Jose, CA (US)

(21) Appl. No.: 19/218,855

(22) Filed: May 27, 2025

Related U.S. Application Data
(60) Provisional application No. 63/653,013, filed on May 29, 2024.

(51) Int. Cl. G11C 16/34; G11C 16/10; G11C 16/30

(52) U.S. Cl. CPC G11C 16/3459; G11C 16/102; G11C 16/30

(57) ABSTRACT

A processing device configures a memory device such that program verify operations are performed for each die of the memory device on different sub-blocks. In configuring the memory device, the processing device configures a first die for performance of program verify operations on a first sub-block within the first die and configures a second die for performance of program verify operations on a second sub-block within the second die. The processing device initiates a programming sequence to write data to the memory device based on the configuring of the memory device. The programming sequence comprises performance of a first program verify operation on the first sub-block within the first die prior to performance of a second program verify operation on the second sub-block within the second die.

### PRIORITY APPLICATION

This application claims the benefit of priority to U.S. Provisional Application Ser. No. 63/653,013, filed May 29, 2024, which is incorporated herein by reference in its entirety.

### TECHNICAL FIELD

Embodiments of the disclosure relate generally to memory sub-systems and, more specifically, to staggering program verify operations in a memory sub-system.

### BACKGROUND

A memory sub-system can be a storage system, such as a solid-state drive (SSD), and can include one or more memory components that store data. The memory components can be, for example, non-volatile memory components and volatile memory components. In general, a host system can utilize a memory sub-system to store data at the memory components and to retrieve data from the memory components.

### BRIEF DESCRIPTION OF THE DRAWINGS

The present disclosure will be understood more fully from the detailed description given below and from the accompanying drawings of various embodiments of the disclosure.

FIG. 1 illustrates an example computing environment that includes a memory sub-system, in accordance with some embodiments of the present disclosure.

FIG. 2 is conceptual diagrams illustrating a technique for managing power consumption of a memory sub-system, in accordance with some embodiments of the present disclosure.

FIG. 3 is a flow diagram illustrating an example method for managing power consumption of a memory sub-system, in accordance with some embodiments of the present disclosure.

FIG. 4 is a block diagram of an example computer system in which embodiments of the present disclosure may operate.

### DETAILED DESCRIPTION

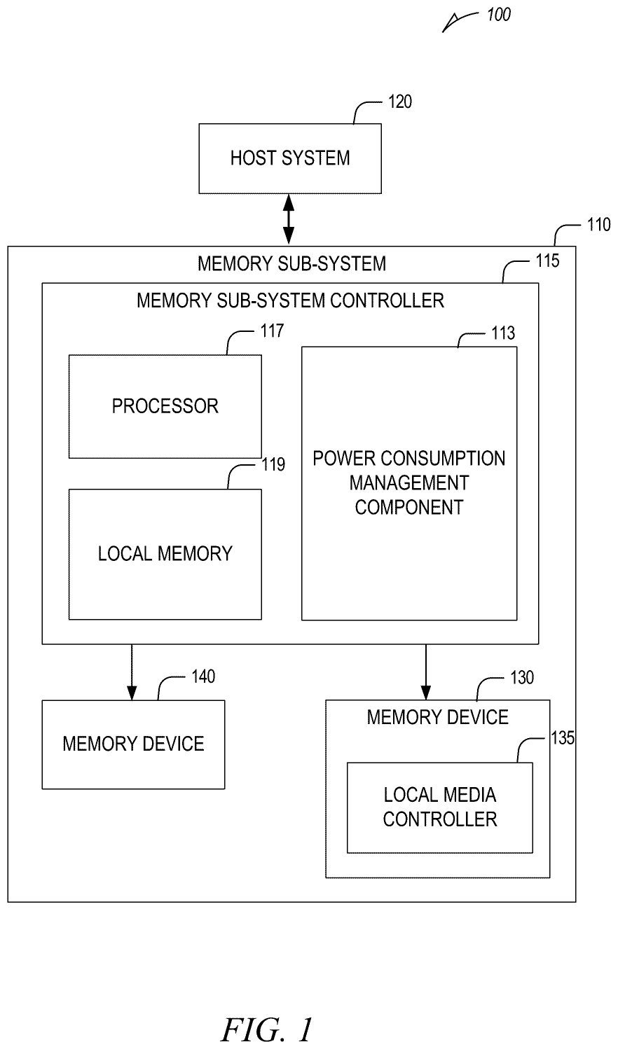

Aspects of the present disclosure are directed to an approach for managing power consumption of a memory sub-system. A memory sub-system can be a storage device (e.g., SSD), a memory module, or a combination of a storage device and memory module. Examples of storage devices and memory modules are described below in conjunction with FIG. 1.

A memory device can be a non-volatile memory device. One example of a non-volatile memory device is a negative-and (NAND) memory device. In general, a host system can utilize a memory sub-system that includes one or more components, such as memory devices that store data. For example, the host system can provide data to be stored at the memory sub-system via the host interface and can request data to be retrieved from the memory sub-system via the host interface. A memory sub-system controller typically receives commands or operations from the host system via the host interface and converts the commands or operations into instructions or appropriate commands to achieve the desired access to the memory components of the memory sub-system.

In memory devices such as NAND memory devices, data programming involves a series of write and verify operations to ensure data integrity, which is referred to as program verify. As an example, during a single-level cell (SLC) program operation, each cell stores one bit of data, and the program verify operation ensures that the correct charge level is achieved for representing either a ‘l’ or a ‘0’. However, this operation can be power-intensive, especially when multiple NAND dies within a device perform these operations simultaneously.

The instantaneous current consumption (ICC) during program verify operations is an important parameter in NAND memory devices because peak ICC occurrences can lead to power budget issues, especially in multi-die configurations where several dies are operating in parallel. To manage this, NAND memory devices employ predictive peak power management (pPPM) algorithms that stagger certain operations of the dies to prevent the system from exceeding the power budget. While effective in managing power, pPPM can lead to performance degradation as it may delay operations, affecting the overall write throughput of the memory device.

Conventional approaches to address these power management issues involve optimizing the program verify algorithms to reduce power consumption, while others focus on hardware solutions such as improving the power delivery network within the device or enhancing the thermal characteristics of the NAND dies to better handle peak power scenarios. Other traditional approaches implement different program verify schemes, such as 1P0V (one program, zero verify) or 1P1V (one program, one verify), which aim to balance the trade-off between programming speed and power consumption. The 1P0V scheme, for example, seeks to eliminate the verify operation to reduce power usage and increase programming speed. However, this can come at the cost of data integrity and may not be suitable for all types of data storage applications. An additional risk of this approach is uncorrectable error correcting code (ECC) without a program status failure.

Aspects of the present disclosure address the above and other issues by configuring a memory device such that program verify operations performed across dies of the memory device are staggered in time rather than performed in parallel. In an example, a power consumption management component configures the dies of the memory device such that program verify operations are performed on different sub-blocks within the dies thereby configuring program verify operations to be staggered in time. Configuring the dies in this manner helps to avoid or at least reduce the likelihood of an occurrence of peak ICC consumption by the memory device, which might otherwise result from program verify operations being performed on the same sub-blocks within the dies. Avoiding occurrences of peak ICC consumption reduces the likelihood of triggering power management protocols (e.g., pPPM) that could throttle the system's performance, thereby maintaining higher operational efficiency.

In addition, distributing the verify operations across different sub-blocks and times, prevents the simultaneous peak power draw that could exceed the system's power budget. This distribution helps in avoiding power-related performance bottlenecks, particularly in multi-die configurations where power management is critical for maintaining system stability and efficiency. This sort of effective power management reduces stress on the memory cells, which can prolong the lifespan of the NAND flash memory by minimizing wear and tear associated with high power consumption and heat generation. Moreover, staggering the program verify operations in this manner means that not all parts of the memory array are tied up in power-intensive verify operations simultaneously, allowing for more continuous and efficient programming cycles.

FIG. 1 illustrates an example computing environment 100 that includes a memory sub-system 110, in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a SSD, a flash drive, a universal serial bus (USB) flash drive, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and a non-volatile dual in-line memory module (NVDIMM).

The computing environment 100 can include a host system 120 that is coupled to one or more memory sub-systems 110. In some embodiments, the host system 120 is coupled to different types of memory sub-system 110. FIG. 1 illustrates one example of a host system 120 coupled to one memory sub-system 110. The host system 120 uses the memory sub-system 110, for example, to write data to the memory sub-system 110 and read data from the memory sub-system 110. As used herein, “coupled to” generally refers to a connection between components, which can be an indirect communicative connection or direct communicative connection (e.g., without intervening components), whether wired or wireless, including connections such as electrical, optical, magnetic, and so forth.

The host system 120 can be a computing device such as a desktop computer, laptop computer, network server, mobile device, embedded computer (e.g., one included in a vehicle, industrial equipment, or a networked commercial device), or such computing device that includes a memory and a processing device. The host system 120 can include or be coupled to the memory sub-system 110 so that the host system 120 can read data from or write data to the memory sub-system 110. The host system 120 can be coupled to the memory sub-system 110 via a physical host interface. Examples of a physical host interface include, but are not limited to, a serial advanced technology attachment (SATA) interface, a peripheral component interconnect express (PCIe) interface, a compute express link (CXL) interface, a USB interface, a Fibre Channel interface, a Serial Attached SCSI (SAS) interface, and so forth. The physical host interface can be used to transmit data between the host system 120 and the memory sub-system 110. The host system 120 can further utilize a Non-Volatile Memory Express (NVMe) interface to access the memory devices 130 and 140 when the memory sub-system 110 is coupled with the host system 120 by the PCIe or CXL interface. The physical host interface provides physical link with multiple communication lanes (also referred to herein simply as “lanes”) for passing control, address, data, and other signals between the memory sub-system 110 and the host system 120.

The memory devices can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

An example of non-volatile memory devices (e.g., memory device 130) includes a NAND type flash memory. Each of the memory devices 130 can include one or more arrays of memory cells such as SLCs, multi-level cells (MLCs) (e.g., TLCs, or quad-level cells [QLCs]). In some embodiments, a particular memory component can include an SLC portion, and an MLC portion, a TLC portion, or a QLC portion of memory cells. Each of the memory cells can store one or more bits of data used by the host system 120. Furthermore, the memory cells of the memory devices 130 can be grouped as memory pages or memory blocks that can refer to a unit of the memory component used to store data.

Although non-volatile memory components such as NAND type flash memory are described, the memory device 130 can be based on any other type of non-volatile memory, such as read-only memory (ROM), phase change memory (PCM), magneto random access memory (MRAM), NOR flash memory, electrically erasable programmable read-only memory (EEPROM), and a cross-point array of non-volatile memory cells. A cross-point array of non-volatile memory can perform bit storage based on a change of bulk resistance in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased.

A memory sub-system controller 115 can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor (processing device) 117 configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, and the like. The local memory 119 can also include ROM for storing micro-code. While the example memory sub-system 110 in FIG. 1 has been illustrated as including the memory sub-system controller 115, in another embodiment of the present disclosure, a memory sub-system 110 may not include a memory sub-system controller 115, and may instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical block address and a physical block address that are associated with the memory devices 130. The memory sub-system controller 115 can further include host interface circuitry to communicate with the host system 120 via the physical host interface. The host interface circuitry can convert the commands received from the host system into command instructions to access the memory devices 130 and convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130.

The memory sub-system 110 also includes a power consumption management component 113 that is responsible for managing power consumption of the memory devices 130 and 140. The power consumption component 113 may utilize multiple techniques for managing power consumption management of the memory devices 130 and 140. As an example, the memory device 130 may comprise multiple dies where each die comprises multiple sub-blocks and the power consumption management component 113 may configure dies such that program verify operations are performed on different sub-blocks within the dies thereby configuring program verify operations to be staggered in time to avoid or at least reduce the likelihood of an occurrence of peak ICC consumption by the memory device 130, which might otherwise result from program verify operations being performed on the same sub-blocks within the dies.

In some embodiments, the memory sub-system controller 115 includes at least a portion of the power consumption management component 113. For example, the memory sub-system controller 115 can include a processor 117 (processing device) configured to execute instructions stored in local memory 119 (e.g., firmware) for performing the operations described herein. In some embodiments, the power consumption management component 113 is part of the host system 120, an application, or an operating system. Further details regarding the power consumption management component 113 are discussed below.

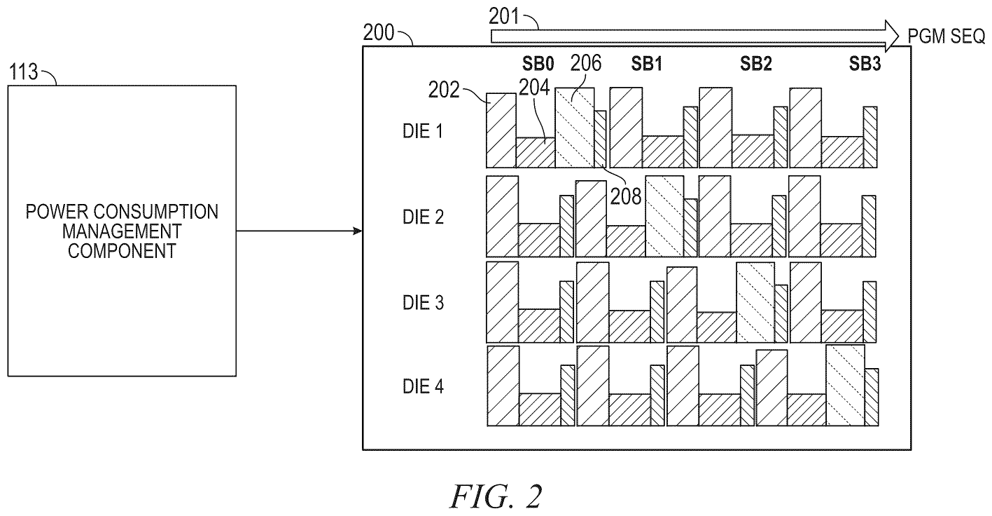

FIG. 2 is conceptual diagrams illustrating a technique for managing power consumption of a NAND memory device 200 in a memory sub-system, in accordance with some embodiments of the present disclosure. In the example illustrated in FIG. 2, the NAND memory device 200 is an example memory device 130.

As shown, the NAND memory device 200 includes multiple NAND dies—die 1, die 2, die 3, and die 4. Each die may include one or more planes and each plane includes multiple blocks. Each block includes a two-or three-dimensional array that includes pages (rows) and strings (columns). A string includes a plurality of memory cells connected in series. Each memory cell is used to represent one or more bit values. For example, a single NAND flash cell includes a transistor that stores an electric charge on a memory layer that is isolated by oxide insulating layers above and below. Within each cell, data is stored as the Vt of the transistor. SLC NAND, for example, can store one bit per cell. Other types of memory cells, such as MLCs, TLCs, QLCs, and penta-level cells (PLCs), can store multiple bits per cell.

A “sub-block,” as referenced herein, refers to a portion of a block such as a sub-set of the pages that form the block. As shown, each die of the memory device 200 includes multiple sub-blocks, each of which are identified by a physical sub-block number. In particular, as shown, each of the dies 1, 2, 3, and 4 include: sub-block 0 (SB0), sub-block 1 (SB1), sub-block 2 (SB2), and sub-block 3 (SB3).

One or more commands may be received (e.g., by the controller 115) from a host system (e.g., host system 120) to write data to the memory device 200. A programming sequence 201 is performed to write the data to the memory device 200. The programming sequence 201 includes multiple phases including: programming pulse application 202; a program voltage (VPGM) plateau 204; program verify 206; and equalization 208.

During programming pulse application 202, various voltage levels are applied to memory cells in the memory device 200 to cause the memory cells to store data. As part of the programming pulse application 202, a VPGM is applied to control gates of memory cells to alter their charge state (e.g., changing the state from ‘1’ to ‘0’). In some examples, the programming pulse application 202 also includes seeding (to drain out residual electrons in channel), bit line (BT) settling (program or inhibit), and VPASS ramping.

The VPGM plateau 204 refers to a period where the VPGM remains constant to ensure uniform programming across the memory array of the sub-block and to minimize errors. The VPGM plateau 204 allows for a controlled and steady application of the VPGM, which helps in achieving consistent programming of the cells.

During program verify 206, a program verify operation is performed on a sub-block to verify the integrity of the data written to the sub-block. That is, the program verify operation is performed to ensure that the data has been correctly and accurately written to the sub-block during the programming pulse application 202. More specifically, the program verify operation is performed to confirm whether cells in the sub-block have reached the correct threshold voltage levels corresponding to the intended data values. Accordingly, program verify 206 involves reading back threshold voltages of cells and comparing them to expected values. If the voltages match the expected values, the data is considered correctly written. If discrepancies are found (the cell voltages do not match the expected values), additional programming pulses may be applied to adjust the cell voltages to the correct levels. This process can be repeated multiple times until the cells reflect the correct data. In some examples, dynamic start voltage acquisition is performed during the program verify 206 phase. Dynamic start voltage acquisition involves adjusting the starting voltage for subsequent programming pulses based on the conditions observed during the current verify operation. This helps to improve the programming process for better efficiency and reliable uniformity across pillar.

The purpose of the equalization 208 phase is to mitigate potential voltage differences between adjacent word lines after programming pulse application 202 and program verify 206 that can lead to issues such as cell-to-cell interference, which can degrade the data integrity and reliability of the NAND memory device. During the equalization 208 phase, voltages of the unselected word lines (those not currently being programmed or verified) are adjusted to a level that minimizes interference with a selected word line (the one that has just been programmed and verified). This adjustment often involves ramping the voltages of the selected word line up or down to a specific “equalization voltage” that is considered safe and non-interfering for the cells on the unselected word lines. The process typically involves carefully controlled voltage ramping that helps in reducing the sharp voltage gradient between the word lines and channels. In this manner, equalization 208 helps to reduce the likelihood of program disturb, where the programming of one cell might unintentionally alter the contents of an adjacent cell. Equalization 208 also aids in maintaining the overall stability and endurance of the NAND memory device 200 by preventing premature wear and tear due to electrical stress.

As shown, the various phases of the programming sequence 201 are repeated multiple times within each die of the memory device 200 with program verify 206 being performed only on certain sub-blocks within each die. That is, while programming pulse application 202, VPGM plateau 204, and equalization 208 are performed at each sub-block in each die, program verify 206 is only performed on a single sub-block in each die. Moreover, as shown, the power management component 113 configures the dies such that program verify operations are performed on different sub-blocks so that the program verify operations are staggered in time rather than performed in parallel, which may trigger peak ICC consumption at the memory device 200. In particular, the power management component 113 configures: die 1 for performance of program verify operations on sub-block 0; die 2 for performance of program verify operations on sub-block 1; die 3 for performance of program verify operations on sub-block 2; and die 4 for performance of program verify operations on sub-block 3. In an example, the power management component 113 selects the sub-blocks within each die based on a power consumption profile associate with each sub-block.

In an example, the power management component 113 configures the dies of the memory device 200 by setting corresponding trim settings of the memory device 200 to specify the sub-blocks within each die at which program verify 206 is to be performed. To set a trim setting, the power management component 113 may cause a particular value to be stored in a corresponding trim register. During the program sequence 201, a local controller (e.g., local controller 135) of the memory device 200 may access the trim settings (e.g., by reading values from the trim registers) to identify which sub-blocks within each die on which to perform program verify 206. The trim settings are dynamic such that the sub-block at which program verify 206 is performed for each die can be adjusted over time based on monitoring power consumption of the memory device 200.

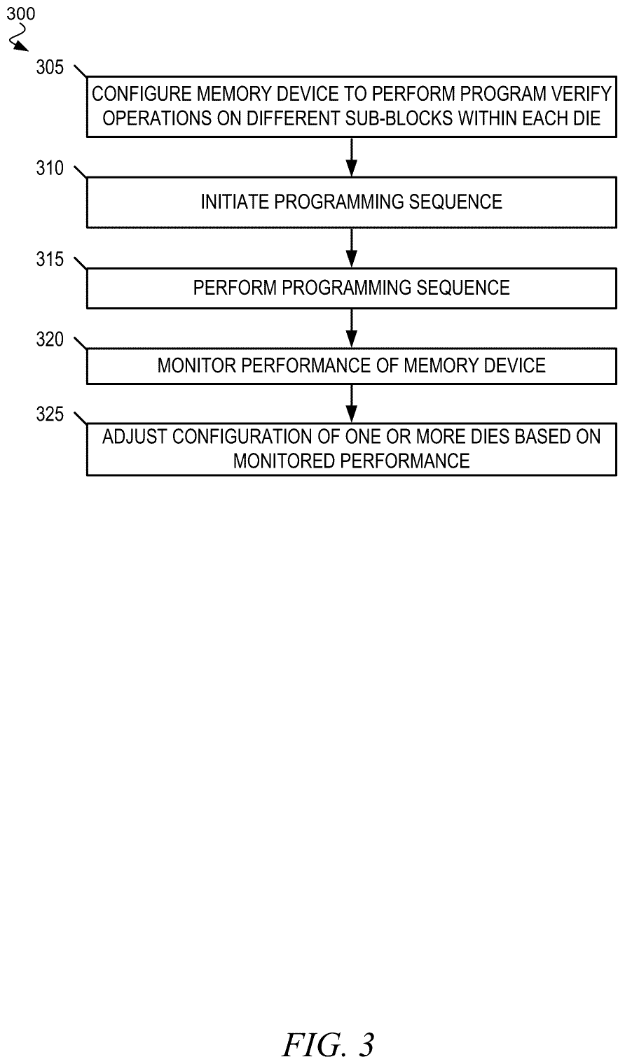

FIG. 3 is a flow diagrams illustrating an example method 300 for managing power consumption of a memory sub-system, in accordance with some embodiments of the present disclosure. The method 300 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some embodiments, the method 300 is performed by the power consumption management component 113 of FIG. 1. Although processes are shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

In the context of FIG. 3, the memory sub-system comprises a memory device, the memory device comprises multiple dies, and each die comprises multiple sub-blocks. Within each die, each sub-block is associated with a physical sub-block number and the same physical sub-block numbers are used in each die. In an example, the memory device includes four dies-die 1, die 2, die 3, and die 4. In this example, each of die 1, die 2, die 3, and die 4 include: sub-block 0, sub-block 1, sub-block 2, and sub-block 3.

At operation 305, a processing device configures the memory device to perform program verify operations on different sub-blocks in each die. That is, the processing device configures each die such that program verify operations are performed on sub-blocks with different physical sub-block numbers in each die. In doing so, the processing device configures the memory device such that program verify operations are staggered in time rather than a traditional approach of performing program verify operations in parallel.

In configuring each die, the memory device selects a sub-block from a given die and configures the die such that program verify operations are performed on the sub-block. In some examples, the processing device may select the sub-block based on power consumption profiles of sub-blocks in the die. The processing device configures a die to perform program verify operations on a given sub-block by setting one or more trim settings for the memory device (e.g., by adding one or more entries to one or more trim registers).

Consistent with the example in which the memory device includes four dies, the processing device configures: die 1 such that program verify operations are performed on sub-block 0; die 2 such that program verify operations are performed on sub-block 1; die 3 such that program verify operations are performed on sub-block 2; and die 4 such that program verify operations are performed on sub-block 3. In this way, none of the program verify operations are performed in parallel and are instead staggered in time.

At operation 310, the processing device initiates a programming sequence to write data to the memory device, and the programming sequence is performed at operation 315 (e.g., by a local controller of the memory device). In some examples, the processing device causes the memory device to perform one or more operations of the programming sequence by sending one or more commands to the memory device. The programming sequence includes multiple phases such as programming pulse application; program voltage (VPGM) plateau; program verify; and equalization, which are discussed in further detail above. The various phases may be repeated multiple times within different dies of the memory device and within different sub-blocks within the dies. Further, program verify operations are performed only on certain sub-blocks within each die. That is, for sub-blocks in a given die other than the sub-block selected for program verify operations, program verify operations are omitted from the program sequence for those sub-blocks.

Consistent with the example in which the memory device includes four dies, the performing of the program sequence includes, among other upstream and downstream operations discussed above, performing a first program verify operation on sub-block 0 of die 1, subsequently performing a second program verify operation is on sub-block 1 of die 2, subsequently performing a third program verify operation on sub-block 2 of die 3, and subsequently performing a fourth program verify operations on sub-block 3 of die 4. In other words, the performance of the first program verify operation is prior to the performance of the second program verify operation, which is prior to the performance of the third program verify operation, which is prior to the performance of the fourth program verify operation. In this way, none of the first program verify operation, the second program verify operation, the third program verify operation, or the fourth program verify operation are performed in parallel. That is, the first program verify operation, the second program verify operation, the third program verify operation, and the fourth program verify operation are staggered in time.

As noted above, the processing device sets one or more trim settings of the memory device to configure the dies to perform program verify operations on different sub-blocks. In some examples, the trim settings are dynamically adjustable. That is, the processing device may adjust the trim settings (and thus the sub-blocks on which program verify operations are performed) during the lifetime of the memory device. For example, the processing device monitors performance of the memory device (at operation 320) including monitoring occurrences of peak current consumption, and adjusts a configuration of one or more dies based on the monitored performance, at operation 325. As an example of the adjusting of the configuration, based on monitoring occurrences of peak ICC consumption in the memory device, the processing device may configure die 1 to perform program verify operations on sub-block 2 while configuring die 3 to perform program verify operations on sub-block 0.

Described implementations of the subject matter can include one or more features, alone or in combination as illustrated below by way of example.

Example 1. A memory sub-system comprising: a memory device comprising a plurality of dies, each die in the plurality of dies comprising a plurality of sub-blocks; a processing device coupled to the memory device, the processing device to perform operations comprising: configuring the memory device such that program verify operations are performed for each die in the plurality of dies on different sub-blocks, the configuring of the memory device comprising: configuring a first die in the plurality of dies for performance of program verify operations on a first sub-block within the first die; and configuring a second die in the plurality of dies for performance of program verify operations on a second sub-block within the second die; and initiating, at the memory device, a programming sequence to write data to the memory device based on the configuring of the memory device, the programming sequence comprising performance of a first program verify operation on the first sub-block within the first die prior to performance of a second program verify operation on the second sub-block within the second die.

Example 2. The memory sub-system of Example 1, wherein the configuring of the memory device comprises configuring each die such that performance of program verify operations during the programming sequence are staggered in time.

Example 3. The memory sub-system of any one or more of Examples 1 or 2, wherein each sub-block in the plurality of sub-blocks in each die in the plurality of dies is associated with a physical sub-block number, the first sub-block is associated with a different physical sub-block number than the second sub-block.

Example 4. The memory sub-system of any one or more of Examples 1-3, wherein: the configuring of the memory device comprises: configuring a third die in the plurality of dies for performance of program verify operations on a third sub-block within the third die; and configuring a fourth die in the plurality of dies for performance of program verify operations on a fourth sub-block within the fourth die; the programming sequence comprises: a third program verify operation performed on the third sub-block within the third die; and a fourth program verify operation performed on the fourth sub-block within the fourth die.

Example 5. The memory sub-system of any one or more of Examples 1-4, wherein none of the first program verify operation, the second program verify operation, the third program verify operation, or the fourth program verify operation are performed in parallel.

Example 6. The memory sub-system of any one or more of Examples 1-5, wherein the configuring of each die comprises setting one or more trim settings for the memory device.

Example 7. The memory sub-system of any one or more of Examples 1-6, wherein the one or more trim settings are dynamically adjustable.

Example 8. The memory sub-system of any one or more of Examples 1-7, wherein the operations comprise: monitoring performance of the memory device; and adjusting a configuration of one or more dies based on the monitoring of the performance of the memory device, the adjusting of the configuration comprising configuring the first die to perform the first program verify operation on a third sub-block in the first die.

Example 9. The memory sub-system of any one or more of Examples 1-8, wherein monitoring performance of the memory device comprises monitoring occurrences of peak instantaneous current consumption, wherein the adjusting of the configuration of one or more dies is based on the monitoring of the occurrences of peak instantaneous current consumption.

Example 10. The memory sub-system of any one or more of Examples 1-9, wherein the processing device is to select a sub-block for each die based on a power consumption profile associated with each sub-block, wherein the selecting comprises: selecting the first sub-block for the first die based on a first power consumption profile associated with the first sub-block; and selecting the second sub-block for the second die based on a second power consumption profile associated with the second sub-block.

Example 11. A method comprising: configuring, by a processing device, a memory device such that program verify operations are performed for each die of the memory device on different sub-blocks, the configuring of the memory device comprising: configuring a first die in the memory device for performance of program verify operations on a first sub-block within the first die; and configuring a second die for performance of program verify operations on a second sub-block within the second die; and performing, at the memory device, a programming sequence to write data to the memory device based on the configuring of the memory device, the performing of the programming sequence comprising performing a first program verify operation on the first sub-block within the first die prior to performing a second program verify operation on the second sub-block within the second die.

Example 12. The method of Example 11, wherein the configuring of memory device comprises configuring each die such that performance of program verify operations during the programming sequence are staggered in time.

Example 13. The method of any one or more of Examples 11 or 12, wherein: each sub-block in in each die of the memory device is associated with a physical sub-block number, and the first sub-block is associated with a different physical sub-block number than the second sub-block.

Example 14. The method of any one or more of Examples 11-13, wherein: the configuring of the memory device comprises: configuring a third die of the memory device for performance of program verify operations on a third sub-block within the third die; and configuring a fourth die in the memory device for performance of program verify operations on a fourth sub-block within the fourth die; the performing of the programming sequence comprises: performing a third program verify operation on the third sub-block within the third die; and performing a fourth program verify operation on the fourth sub-block within the fourth die.

Example 15. The method of any one or more of Examples 11-14, wherein none of the first program verify operation, the second program verify operation, the third program verify operation, or the fourth program verify operation are performed in parallel.

Example 16. The method of any one or more of Examples 11-15, wherein the configuring of each die comprises setting one or more trim settings for the memory device.

Example 17. The method of any one or more of Examples 11-16, wherein the one or more trim settings are dynamically adjustable.

Example 18. The method of any one or more of Examples 11-17, comprising: monitoring performance of the memory device; and adjusting a configuration of one or more dies based on the monitoring of the performance of the memory device, the adjusting of the configuration comprising configuring the first die to perform the first program verify operation on a third sub-block in the first die.

Example 19. The method of any one or more of Examples 11-18, comprising selecting a sub-block for each die based on a power consumption profile associated with each sub-block, wherein the selecting comprises: selecting the first sub-block for the first die based on a first power consumption profile associated with the first sub-block; and selecting the second sub-block for the second die based on a second power consumption profile associated with the second sub-block.

Example 20. A computer-readable storage medium comprising instructions that, when executed by a processing device, configure the processing device to perform operations comprising: configuring, by a processing device, a memory device such that program verify operations are performed for each die in the memory device on different sub-blocks, the configuring of the memory device comprising: configuring a first die in the memory device for performance of program verify operations on a first sub-block within the first die; and configuring a second die for performance of program verify operations on a second sub-block within the second die; and initiating, at the memory device, a programming sequence to write data to the memory device based on the configuring of the memory device, the programming sequence comprising performance of a first program verify operation on the first sub-block within the first die prior to performance of a second program verify operation on the second sub-block within the second die.

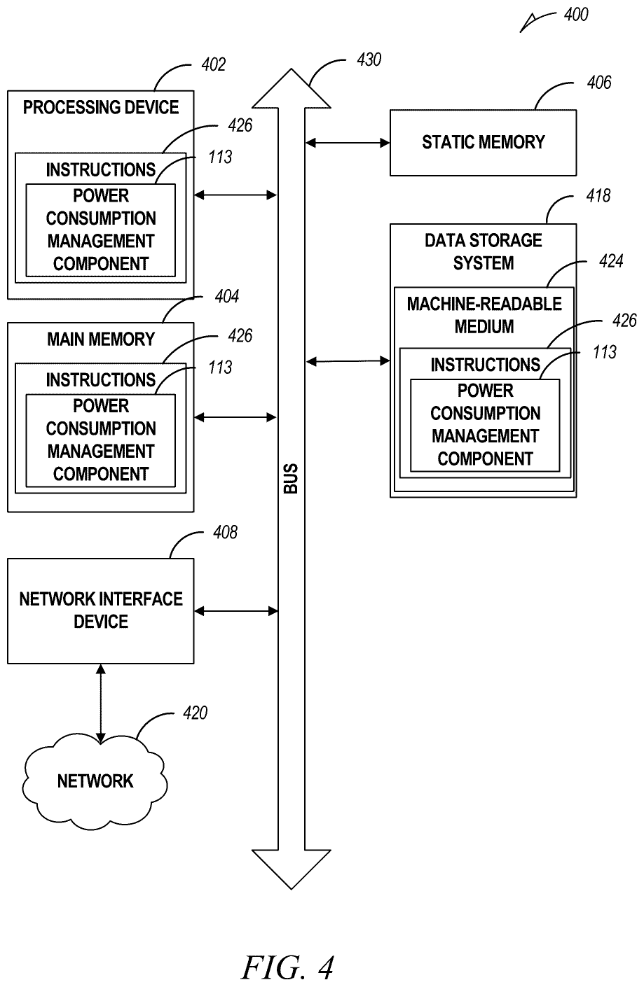

FIG. 4 illustrates an example machine in the form of a computer system within which a set of instructions can be executed for causing the machine to perform any one or more of the methodologies discussed herein. FIG. 4 illustrates an example machine of a computer system 400 within which a set of instructions, for causing the machine to perform any one or more of the methodologies discussed herein, can be executed. In some embodiments, the computer system 400 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the power consumption management component 113 of FIG. 1). In alternative embodiments, the machine can be connected (e.g., networked) to other machines in a local area network (LAN), an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 400 includes a processing device 402, a main memory 404 (e.g., ROM, flash memory, DRAM such as SDRAM or RDRAM, etc.), a static memory 406 (e.g., flash memory, static random access memory (SRAM), etc.), and a data storage system 418, which communicate with each other via a bus 430.

Processing device 402 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 402 can also be one or more special-purpose processing devices such as an ASIC, a FPGA, a digital signal processor (DSP), network processor, or the like. The processing device 402 is configured to execute instructions 426 for performing the operations and steps discussed herein. The computer system 400 can further include a network interface device 408 to communicate over a network 420.

The data storage system 418 can include a machine-readable storage medium 424 (also known as a computer-readable medium) on which is stored one or more sets of instructions 426 or software embodying any one or more of the methodologies or functions described herein. The instructions 426 can also reside, completely or at least partially, within the main memory 404 and/or within the processing device 402 during execution thereof by the computer system 400, the main memory 404 and the processing device 402 also constituting machine-readable storage media. The machine-readable storage medium 424, data storage system 418, and/or main memory 404 can correspond to the memory sub-system 110 of FIG. 1.

In one embodiment, the instructions 426 include instructions to implement functionality corresponding to a link management component (e.g., the power consumption management component 113 of FIG. 1). While the machine-readable storage medium 424 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, ROMs, RAMs, EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a ROM, RAM, magnetic disk storage media, optical storage media, flash memory components, etc.

In the foregoing specification, embodiments of the disclosure have been described with reference to specific example embodiments thereof. It will be evident that various modifications can be made thereto without departing from the broader scope of embodiments of the disclosure as set forth in the following claims. The specification and drawings are, accordingly, to be regarded in an illustrative sense rather than a restrictive sense.

What is claimed is:

1. A memory sub-system comprising:
a memory device comprising a plurality of dies, each die in the plurality of dies comprising a plurality of sub-blocks;
a processing device coupled to the memory device, the processing device to perform operations comprising:
configuring the memory device such that program verify operations are performed for each die in the plurality of dies on different sub-blocks, the configuring of the memory device comprising:
configuring a first die in the plurality of dies for performance of program verify operations on a first sub-block within the first die; and
configuring a second die in the plurality of dies for performance of program verify operations on a second sub-block within the second die; and
initiating, at the memory device, a programming sequence to write data to the memory device based on the configuring of the memory device, the programming sequence comprising performance of a first program verify operation on the first sub-block within the first die prior to performance of a second program verify operation on the second sub-block within the second die.

2. The memory sub-system of claim 1, wherein the configuring of the memory device comprises configuring each die such that performance of program verify operations during the programming sequence are staggered in time.

3. The memory sub-system of claim 1, wherein each sub-block in the plurality of sub-blocks in each die in the plurality of dies is associated with a physical sub-block number, the first sub-block is associated with a different physical sub-block number than the second sub-block.

4. The memory sub-system of claim 1, wherein:
the configuring of the memory device comprises:
configuring a third die in the plurality of dies for performance of program verify operations on a third sub-block within the third die; and
configuring a fourth die in the plurality of dies for performance of program verify operations on a fourth sub-block within the fourth die;
the programming sequence comprises:
a third program verify operation performed on the third sub-block within the third die; and
a fourth program verify operation performed on the fourth sub-block within the fourth die.

5. The memory sub-system of claim 4, wherein none of the first program verify operation, the second program verify operation, the third program verify operation, or the fourth program verify operation are performed in parallel.

6. The memory sub-system of claim 1, wherein the configuring of each die comprises setting one or more trim settings for the memory device.

7. The memory sub-system of claim 6, wherein the one or more trim settings are dynamically adjustable.

8. The memory sub-system of claim 1, wherein the operations comprise:
monitoring performance of the memory device; and
adjusting a configuration of one or more dies based on the monitoring of the performance of the memory device, the adjusting of the configuration comprising configuring the first die to perform the first program verify operation on a third sub-block in the first die.

9. The memory sub-system of claim 8, wherein monitoring performance of the memory device comprises monitoring occurrences of peak instantaneous current consumption, wherein the adjusting of the configuration of one or more dies is based on the monitoring of the occurrences of peak instantaneous current consumption.

10. The memory sub-system of claim 1, wherein the processing device is to select a sub-block for each die based on a power consumption profile associated with each sub-block, wherein the selecting comprises:
selecting the first sub-block for the first die based on a first power consumption profile associated with the first sub-block; and
selecting the second sub-block for the second die based on a second power consumption profile associated with the second sub-block.

11. A method comprising:
configuring, by a processing device, a memory device such that program verify operations are performed for each die of the memory device on different sub-blocks, the configuring of the memory device comprising:
configuring a first die in the memory device for performance of program verify operations on a first sub-block within the first die; and
configuring a second die for performance of program verify operations on a second sub-block within the second die; and
performing, at the memory device, a programming sequence to write data to the memory device based on the configuring of the memory device, the performing of the programming sequence comprising performing a first program verify operation on the first sub-block within the first die prior to performing a second program verify operation on the second sub-block within the second die.

12. The method of claim 11, wherein the configuring of memory device comprises configuring each die such that performance of program verify operations during the programming sequence are staggered in time.

13. The method of claim 11, wherein:
each sub-block in in each die of the memory device is associated with a physical sub-block number, and
the first sub-block is associated with a different physical sub-block number than the second sub-block.

14. The method of claim 11, wherein:
the configuring of the memory device comprises:
configuring a third die of the memory device for performance of program verify operations on a third sub-block within the third die; and
configuring a fourth die in the memory device for performance of program verify operations on a fourth sub-block within the fourth die;
the performing of the programming sequence comprises:
performing a third program verify operation on the third sub-block within the third die; and
performing a fourth program verify operation on the fourth sub-block within the fourth die.

15. The method of claim 14, wherein none of the first program verify operation, the second program verify operation, the third program verify operation, or the fourth program verify operation are performed in parallel.

16. The method of claim 11, wherein the configuring of each die comprises setting one or more trim settings for the memory device.

17. The method of claim 16, wherein the one or more trim settings are dynamically adjustable.

18. The method of claim 11, comprising:
monitoring performance of the memory device; and
adjusting a configuration of one or more dies based on the monitoring of the performance of the memory device, the adjusting of the configuration comprising configuring the first die to perform the first program verify operation on a third sub-block in the first die.

19. The method of claim 11, comprising selecting a sub-block for each die based on a power consumption profile associated with each sub-block, wherein the selecting comprises:
selecting the first sub-block for the first die based on a first power consumption profile associated with the first sub-block; and
selecting the second sub-block for the second die based on a second power consumption profile associated with the second sub-block.

20. A computer-readable storage medium comprising instructions that, when executed by a processing device, configure the processing device to perform operations comprising:
configuring, by a processing device, a memory device such that program verify operations are performed for each die in the memory device on different sub-blocks, the configuring of the memory device comprising:
configuring a first die in the memory device for performance of program verify operations on a first sub-block within the first die; and
configuring a second die for performance of program verify operations on a second sub-block within the second die; and
initiating, at the memory device, a programming sequence to write data to the memory device based on the configuring of the memory device, the programming sequence comprising performance of a first program verify operation on the first sub-block within the first die prior to performance of a second program verify operation on the second sub-block within the second die.
